(19) United States
(12) Patent Application Publication
(10) Pub. No.: US 2024/0170624 A1
(43) Pub. Date: May 23, 2024

(54) MANUFACTURING METHOD OF OPTICAL MEMBER AND MANUFACTURING METHOD OF LIGHT-EMITTING DEVICE

(71) Applicant: NICHIA CORPORATION, Anan-shi (JP)

(72) Inventor: Naoki MUSASHI, Anan-shi (JP)

(21) Appl. No.: 18/513,504

(22) Filed: Nov. 17, 2023

(30) Foreign Application Priority Data
Nov. 21, 2022 (JP) 2022-185409
Jun. 15, 2023 (JP) 2023-098165

(51) Int. Cl. H01L 33/58; H01L 25/075

(52) U.S. Cl. CPC H01L 33/58; H01L 25/0753; H01L 2933/0058

(57) ABSTRACT

A manufacturing method of an optical member includes: preparing an optical member intermediate having light transmissivity, the optical member intermediate including an upper surface including a peripheral portion and recessed portions recessed from the peripheral portion, the peripheral portion including first regions and second regions, each of the first regions being defined by a circle surrounded by three or more of the recessed portions and passing through a point on an outer edge of each of the three or more of the recess portions in a top view; and irradiating the upper surface of the optical member intermediate with plasma under an atmosphere containing at least one selected from the group consisting of an oxygen radical, CF₄, CHF₃, and SF₆ to make a height of a center of each of the first regions to be higher than a height of each of the second regions.

### CROSS-REFERENCE TO RELATED APPLICATION

This application claims priority to Japanese Patent Application No. 2022-185409, filed on Nov. 21, 2022, and Japanese Patent Application No. 2023-098165 filed on Jun. 15, 2023, the disclosures of which are hereby incorporated herein by reference in their entirety.

### BACKGROUND OF THE INVENTION

The present disclosure relates to a manufacturing method of an optical member and a manufacturing method of a light-emitting device.

A method of forming an uneven shape on a surface of a light-transmissive member has been known (Japanese Patent Publication No: JP 2017-032806 A, Japanese Patent Publication No: JP 2016-001639 A).

### SUMMARY

There are provided a manufacturing method of an optical member provided with protrusions and recessions formed on its surface and a manufacturing method of a light-emitting device.

The present disclosure includes the following configuration.

A manufacturing method of an optical member according to one embodiment includes: preparing an optical member intermediate having light transmissivity, the optical member intermediate including an upper surface including a peripheral portion and a plurality of recessed portions each surrounded by the peripheral portion and recessed from the peripheral portion, the peripheral portion including a plurality of first regions and a plurality of second regions each sandwiched between adjacent ones of the first regions, each of the first regions being defined by a circle surrounded by three or more of the recessed portions and passing through a point on an outer edge of each of the three or more of the recess portions in a top view; and irradiating the upper surface of the optical member intermediate with plasma under an atmosphere containing at least one selected from the group consisting of an oxygen radical, CF₄, CHF₃, and SF₆ to make a height of a center of each of the first regions to be higher than a height of each of the second regions as measured from a lower surface of the optical member intermediate.

A manufacturing method of a light-emitting device according to one embodiment includes: preparing a light-emitting device intermediate including a light-emitting element, and an optical member intermediate including an upper surface and a plurality of recessed portions formed in the upper surface and spaced apart from each other, the upper surface including a plurality of first regions and a plurality of second regions each sandwiched between adjacent ones of the first regions, each of the first regions being defined by a circle surrounded by three or more of the recessed portions and passing through a point on an outer edge of each of the three or more of the recess portions in a top view; and irradiating the upper surface of the optical member intermediate with plasma under an atmosphere containing at least one selected from the group consisting of an oxygen radical, CF₄, CHF₃, and SF₆ to make a height of a center of each of the first regions to be higher than a height of each of the second regions as measured from a lower surface of the optical member intermediate.

According to an embodiment of the present disclosure, there are provided a manufacturing method of an optical member provided with protrusions and recessions formed on its surface, a light-emitting device including the optical member, and a manufacturing method of the light-emitting device.

### BRIEF DESCRIPTION OF DRAWINGS

FIG. 1A is a schematic perspective view illustrating an optical member intermediate according to an embodiment.

FIG. 1B is a schematic top view illustrating a part of the optical member intermediate according to the embodiment.

FIG. 1C is a schematic top view illustrating a part of the optical member intermediate according to the embodiment.

FIG. 1D is a schematic end view illustrating a cross-sectional surface taken along the line ID-ID of FIG. 1C.

FIG. 1E is a schematic top view illustrating a part of the optical member intermediate according to the embodiment.

FIG. 1F is a schematic end view illustrating a cross-sectional surface taken along the line IF-IF of FIG. 1E.

FIG. 2A is a schematic top view illustrating a part of an optical member according to the embodiment.

FIG. 2B is a schematic top view illustrating a part of the optical member according to the embodiment.

FIG. 2C is a schematic end view illustrating a cross-sectional surface taken along the line IIC-IIC of FIG. 2B.

FIG. 2D is a schematic top view illustrating a part of the optical member according to the embodiment.

FIG. 2E is a schematic end view illustrating a cross-sectional surface taken along the line IIE-IIE of FIG. 2D.

FIG. 3A is a schematic top view illustrating a part of an optical member according to an embodiment.

FIG. 3B is a schematic top view illustrating a part of the optical member according to the embodiment.

FIG. 3C is a schematic end view illustrating a cross-sectional surface taken along the line IIIC-IIIC of FIG. 3B.

FIG. 3D is a photograph showing a part of the optical member according to the embodiment.

FIG. 3E is a photograph showing a part of the optical member according to the embodiment.

FIG. 4 is a schematic top view illustrating a part of an optical member intermediate according to an embodiment.

FIG. 5 is a schematic top view illustrating a part of an optical member intermediate according to an embodiment.

FIG. 6 is a schematic top view illustrating a part of an optical member intermediate according to an embodiment.

FIG. 7 is a schematic cross-sectional view illustrating a light-emitting device according to an embodiment.

FIG. 8A is a schematic diagram illustrating a manufacturing method of the light-emitting device according to the embodiment.

FIG. 8B is a schematic diagram illustrating the manufacturing method of the light-emitting device according to the embodiment.

FIG. 8C is a schematic diagram illustrating the manufacturing method of the light-emitting device according to the embodiment.

FIG. 8D is a schematic diagram illustrating the manufacturing method of the light-emitting device according to the embodiment.

FIG. 8E is a schematic diagram illustrating the manufacturing method of the light-emitting device according to the embodiment.

FIG. 9A is a schematic cross-sectional view illustrating a light-emitting device according to an embodiment.

FIG. 9B is a schematic cross-sectional view taken along the line IXB-IXB of FIG. 9A.

FIG. 10A is a schematic perspective view illustrating a light-emitting device intermediate according to an embodiment.

FIG. 10B is a schematic top view illustrating the light-emitting device intermediate according to the embodiment.

FIG. 11A is a graph showing the transmittances of examples.

FIG. 11B is a graph showing the transmittances of examples.

### DETAILED DESCRIPTION

Hereinafter, the present invention will be described in detail with reference to the drawings. In the following description, terms indicating a specific directions or positions (e.g., “upper”, “lower”, and other terms including those terms) are used as necessary. The use of those terms, however, is to facilitate understanding of the invention with reference to the drawings, and the technical scope of the present invention is not limited by the meaning of those terms. Parts having the same reference signs appearing in a plurality of drawings indicate identical or equivalent parts or members. The same name may be used for each member even when the state, shape, or the like of the member differs, for example, between before and after curing, between before and after cutting, or the like.

Further, the following embodiments exemplify optical members and light-emitting devices for embodying the technical concept of the present invention, and the present invention is not limited to the embodiments described below. The dimensions, materials, shapes, relative arrangements, and the like of constituent components described below are not intended to limit the scope of the present invention to those alone, but are intended to provide an example, unless otherwise specified. The contents described in one embodiment can be applied to other embodiments. The sizes, positional relationship, and the like of the members illustrated in the drawings may be exaggerated to clarify the explanation.

In the manufacturing method according to the present embodiment, an optical member or a light-emitting device can be obtained by irradiating a prepared intermediate with plasma. In the present specification, the intermediate that becomes the optical member by plasma irradiation may be referred to as an “optical member intermediate”. Among intermediates, an intermediate that becomes a light-emitting device by plasma irradiation may be referred to as a “light-emitting device intermediate”.

The upper surface of the prepared intermediate includes a peripheral portion and a plurality of recessed portions recessed from the peripheral portion. The recessed portions are spaced apart from each other. The peripheral portion is a flat surface. Here, the “flat surface” includes a surface provided with minute protrusions and recessions or the like inevitably formed in a manufacturing process or the like. For example, a surface having a surface roughness Ra of about 20 nm or less is defined as a flat surface. The recessed portions can be formed through a step of forming recessed portions in the step of preparing the intermediate. When an intermediate provided with a plurality of recessed portions is purchased and prepared in advance, the step of forming recessed portions can be omitted.

The peripheral portion includes circular first regions and second regions each surrounded by the first regions. Each of the first regions is defined by a circle surrounded by three or more of the recessed portions and passing through a point on an outer edge of each of the three or more of the recess portions in a top view. The second region can be defined as a region of a portion located on a straight line connecting the centers of the two adjacent recessed portions. Alternatively, the second region can be defined as a region including a portion located around one recessed portion and located on the straight line connecting the centers of the two adjacent first regions. In the intermediate, the first region and the second region are on the same plane, and in other words are located at the same height as measured from a lower surface of the intermediate. Note that a circle that is the outer edge of the first region and serves as a boundary between the first region and the second region is an imaginary circle present at the position defined as described above, and is not visible.

By plasma irradiation, the depth of the recessed portion of the optical member or the depth of the recessed portion of the light-emitting device becomes deeper than the depth of the recessed portion of the intermediate of each of them. In addition, the opening diameter of the recessed portion of the optical member or the opening diameter of the recessed portion of the light-emitting device is larger than the opening diameter of the recessed portion of the intermediate of each of them. As described above, in the optical member or the light-emitting device, the height of the center of the first region is higher than the height of the second region on the upper surface surrounding each of the recessed portions (the recessed portion of the optical member or the recessed portion of the light-emitting device).

Here, the “height of the second region” in the optical member or the light-emitting device obtained after plasma irradiation can be defined as the height of a portion located at a portion where a straight line connecting the centers of the two adjacent recessed portions intersects with a straight line connecting the centers of the two adjacent first regions located around one recessed portion.

When the shape of the upper surface of the intermediate changes between before and after the plasma irradiation, the position of the boundary between the peripheral portion and the recessed portion changes, and the boundary between the first region and the second region of the peripheral portion becomes unclear. Specifically, because plasma irradiation changes at least a part of the peripheral portion from a flat surface to a recessed surface formed by plasma ablation, and a part or all of the recessed surface is integrated with the recessed portion before the plasma irradiation to constitute a part of another recessed portion.

However, the positions of the center of the recessed portion and the center of the first region in a plan view do not change between before and after the plasma irradiation. That is, the position of the second region located at the portion where the straight line connecting the centers of the two adjacent recessed portions intersects with the straight line connecting the centers of the two adjacent first regions located around one recessed portion does not change. Therefore, by thus defining the height of the second region whose position in a plan view does not change between before and after the plasma irradiation, even when the shape changes between before and after the plasma irradiation, the position can be identified.

When the intermediate is irradiated with plasma, the surface thereof reacts with a component contained in the plasma and is removed. Therefore, as the plasma irradiation proceeds, the reaction proceeds, and thus the height of the peripheral portion of the intermediate becomes lower in the thickness direction.

The plasma used in the present embodiment is capacitively coupled plasma, and the progress of the reaction when dry etching is performed using this plasma is not anisotropic but isotropic. That is, the reaction proceeds not only in a direction perpendicular to the upper surface but also in a direction parallel to the upper surface (horizontal direction). Thus, the recessed portion of the optical member or the recessed portion of the light-emitting device having an opening diameter larger than the opening diameter of the recessed portion of the intermediate of the optical member or the light-emitting device is formed. By performing such dry etching, the surface irradiated with plasma is easily roughened, and a light diffusion effect is easily obtained.

The increase in the opening diameter of the recessed portion as the reaction proceeds means that the area of the flat surface, that is, the peripheral portion becomes small. In particular, at the upper end (opening portion) of the recessed portion, both of the reaction in the vertical direction and the reaction in the horizontal direction proceed at the same time, and the peripheral portion at the position closer to the recessed portion is more likely to be removed. That is, in a top view, a portion that is a part of the peripheral portion before the reaction is incorporated into a part of the recessed portion as the reaction proceeds. In other words, at least a part of a region of the first region excluding its center and at least a part of the second region of the peripheral portion before the reaction become a part of the recessed portion after the reaction.

In the peripheral portion, the center of the circular first region surrounded by three or more of the recessed portions and passing through a point on an outer edge of each of the three or more of the recess portions is located at a position farthest from the recessed portions. The entire second region sandwiched between the first regions is located at a position closer to the recessed portion than the centers of the first regions are. That is, compared with the second region, the center of the first region is less likely to be affected by the reaction proceeding in the horizontal direction. In other words, the center of the first region is less likely to be removed than the second region. Therefore, the height of the center of the first region is likely to be higher than that of the second region. The peripheral portion (a portion other than the center) of the first region is also likely to be removed more than the center of the first region. Therefore, the central portion of the first region tends to be higher than the peripheral portion of the first region.

As described above, using plasma which causes the reaction to proceed isotropically allows the optical member to have a shape which is difficult to obtain only by a method of providing a height difference by partial removal by etching using a mask, or the like.

The optical member thus obtained exhibits optical properties different from those of the optical member intermediate. Similarly, the light-emitting device exhibits optical properties different from those of the light-emitting device intermediate.

Here, a flat plate-shaped light-transmissive member, the optical member intermediate, and the optical member are compared. The optical member intermediate is obtained by processing the flat plate-shaped light-transmissive member, and the optical member is obtained by processing the optical member intermediate. In other words, these three are made of the same material.

As an example, a case where recessed portions of the optical member intermediate are extremely fine recessed portions having an opening diameter (diameter) of about 0.5 μm to 1 μm, a depth of about 0.1 μm to 0.5 μm, and a pitch (a distance between the centers of the recessed portions) of about 0.8 μm to 1.2 μm will be described. The optical member has recessed portions having a larger opening diameter and a deeper depth than the optical member intermediate, and includes almost no peripheral portion (flat surface). When the transmittances of the optical member intermediate and the optical member are compared, they are higher than the transmittance of the flat plate-shaped light-transmissive member at all wavelengths, that is, at a wavelength of infrared light, a wavelength of visible light, and a wavelength of ultraviolet light. At a wavelength shorter than about 500 nm, the transmittance of the optical member is higher than the transmittance of the optical member intermediate. For example, in a wavelength band shorter than 480 nm, the transmittance of the optical member is higher than the transmittance of the optical member intermediate by about 0.1% to 3%. In particular, as the wavelength is shorter in this range, the transmittance of the optical member is higher than the transmittance of the optical member intermediate by about 1% to 3%. Further, at a wavelength longer than about 560 nm, the transmittance of the optical member is lower than the transmittance of the optical member intermediate. Further, at a wavelength longer than about 580 nm, the transmittance of the optical member is lower than the transmittance of the optical member intermediate by about 0.1% to 1%. That is, the optical member transmits light more easily than the optical member intermediate on the short wavelength side, and transmits light less easily than the optical member intermediate on the long wavelength side.

As another example, a case where recessed portions of the optical member intermediate are fine recessed portions having an opening diameter (diameter) of about 3 μm to 5 μm, a depth of about 1 μm to 3 μm, and a pitch (a distance between the centers of the recessed portions) of about 4.8 μm to 5.2 μm will be described. Also in this case, the optical member is provided with recessed portions having a larger opening diameter and a deeper depth than the optical member intermediate, and includes almost no peripheral portion (flat surface). When the transmittances of the optical member and the optical member intermediate are compared, first, on the short wavelength side, they are lower than the transmittance of a flat plate-shaped light-transmissive member. The transmittance of the optical member intermediate is lower than the transmittance of the flat plate-shaped light-transmissive member at a wavelength of about 700 nm or less. The transmittance of the optical member is lower than the transmittance of the flat plate-shaped light-transmissive member at a wavelength of about 650 nm or less. At a wavelength shorter than about 500 nm, the transmittance of the optical member is lower than the transmittance of the optical member intermediate. For example, the transmittance of the optical member is lower than the transmittance of the flat plate-shaped light-transmissive member at a wavelength of about 650 nm or less. Further, at a wavelength longer than about 550 nm, the transmittance of the optical member is higher than the transmittance of the optical member intermediate. At a wavelength shorter than about 500 nm, the transmittance of the optical member is lower than the transmittance of the optical member intermediate by about 2% to 10%. Further, at a wavelength longer than about 550 nm, the transmittance of the optical member is higher than the transmittance of the optical member intermediate. For example, at a wavelength longer than about 550 nm, the transmittance of the optical member is higher than the transmittance of the optical member intermediate by about 0.1% to 10%.

As described above, the optical properties of the light-emitting device can be adjusted by using a change in the transmittance at each wavelength depending on the size of the recessed portions.

### First Embodiment

A manufacturing method of an optical member according to the first embodiment includes the following steps.
(1-1) Step of preparing an optical member intermediate provided with recessed portions on the upper surface thereof
(1-2) Step of irradiating the optical member intermediate with plasma

The steps will be described in detail below.

(1-1) Step of Preparing an Optical Member Intermediate Provided with a Plurality of Recessed Portions

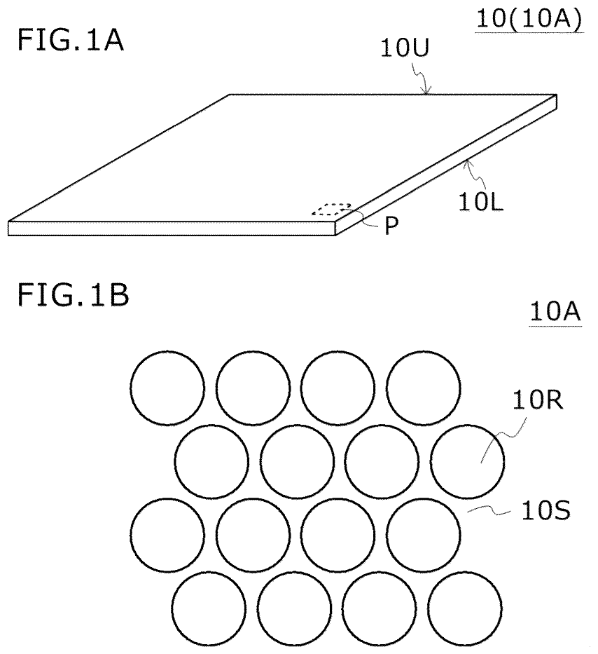

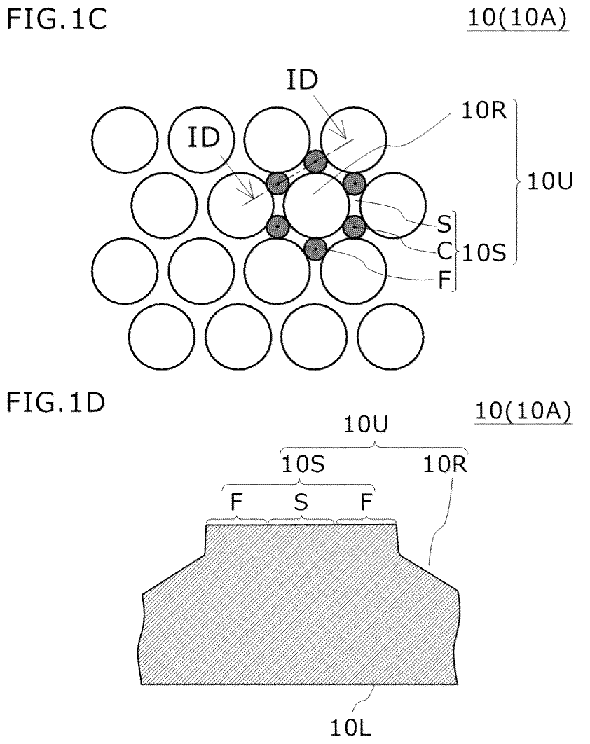

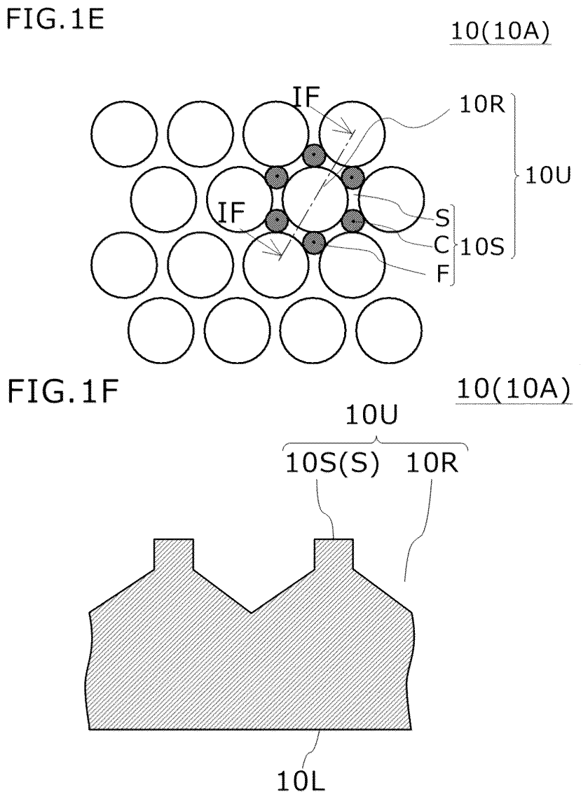

FIG. 1A is a schematic perspective view illustrating an example of an optical member intermediate 10A. FIGS. 1B to 1F are schematic enlarged views and schematic end views in which a portion P of FIG. 1A is enlarged. The optical member intermediate 10A is, for example, a sheet-like member. The top view shape of the optical member intermediate 10A can be, for example, instead of a quadrangular shape as illustrated in FIG. 1A, a polygonal shape, such as a triangular shape, a pentagonal shape, or a hexagonal shape, a circular shape, an elliptical shape, a shape in which a part of these shapes is missing, a shape in which these shapes are combined, or the like. The size of one side or the diameter of the optical member intermediate 10A can be, for example, in a range from 1 cm to 30 cm. The thickness of the optical member intermediate 10A (the distance between the upper surface and the lower surface in the peripheral portion) can be, for example, in a range from 0.1 mm to 5 mm.

The optical member intermediate 10A includes an upper surface 10U and a lower surface 10L. The upper surface 10U includes a peripheral portion 10S and at least three recessed portions 10R. Each of the recessed portions 10R is surrounded by the peripheral portion 10S and is separated from the adjacent recessed portions 10R.

In the example illustrated in FIG. 1B, the opening portion shape of the recessed portion 10R in a top view is a circular shape. Each recessed portion 10R is disposed such that the center of the recessed portion 10R is positioned at a respective one of the lattice points of a triangular lattice in a top view. In this case, one recessed portion 10R is surrounded by six recessed portions 10R via the surrounding peripheral portion 10S.

The opening diameter (diameter) of the recessed portion 10R can be set to, for example, in a range from 0.2 μm to 50 μm. The distance between the recessed portions 10R (the distance between the centers of the recessed portions in a top view) can be, for example, a length in a range from 101% to 150% of the opening diameter of the recessed portion 10R.

In addition, all of the recessed portions 10R may have the same opening diameter, or may have different opening diameters. For example, the recessed portions 10R may include a first recessed portion having an opening diameter in a range from 0.2 μm to 1 μm and a depth in a range from 0.5 μm to 1.5 μm and a second recessed portion having an opening diameter in a range from 3 μm to 5 μm and a depth in a range from 4.5 μm to 5.5 μm. For example, a region including the first recessed portion can have a circular shape and regions each including the second recessed portion can be provided around the circular shape. Alternatively, a region including the second recessed portion can have a circular shape and regions each including the first recessed portion can be provided around the circular shape. In this manner, when a plurality of the regions having different opening diameters are provided, there is a region in which a circle passing through a point on an outer edge of each of the three or more of the recess portions cannot be defined at boundaries between the regions. In this case, an ellipse passing through a point on an outer edge of each of three or more recessed portions can be used instead of the circle. In addition, recessed portions having different opening diameters may be alternately disposed, and even in such a case, when a circle passing through a point on an outer edge of each of three or more of the recess portions cannot be defined, an ellipse passing through a point on an outer edge of each of three or more recessed portions can be used instead of the circle.

The recessed portion 10R is a portion recessed in, for example, a columnar shape, a conical shape, a truncated conical shape, a shape obtained by combining these shapes, a partially deformed shape, or the like. The inner surface defining the recessed portion 10R can be a surface perpendicular to and/or inclined with respect to the upper surface 10U. In the example illustrated in FIGS. 1D, 1F, and the like, the inner surface defining the recessed portion 10R is a surface in which a portion continuous from the opening portion is perpendicular to the upper surface 10U and a surface in which a portion on the lower side of the portion is inclined with respect to the upper surface 10U. The deepest portion of the recessed portion 10R can be located, for example, at the center of the recessed portion 10R in a top view. The depth of the deepest portion of the recessed portion 10R can be, for example, in a range from 0.1 μm to 10 μm. In addition, from another viewpoint, the depth of the deepest portion of the recessed portion 10R can be, for example, in a range from 1% to 90% of the thickness of the optical member intermediate 10A.

The peripheral portion 10S of the optical member intermediate 10A includes first regions F and second regions S. As illustrated in FIG. 1E, the first region F is a region defined by a circle surrounded by three recessed portions 10R and passing through a point on an outer edge of each of the three recessed portions 10R in a top view. The first regions F are illustrated as hatched circular regions in FIGS. 1C and 1E. The first region F is located in the same plane with the second region S as illustrated in FIG. 1D and the like.

The second region S is a region sandwiched between the first regions F in the peripheral portion 10S. Each recessed portion 10R is in contact with six first regions F and six second regions S. Each first region F is in contact with three second regions S and three recessed portions 10R. Each second region S is in contact with two recessed portions 10R and two first regions F. Centers C of the first regions F are disposed at regular intervals around each of the recessed portions 10R provided with circular openings. The centers C of the six first regions F are located on the circumference of an imaginary circle having the center matching the center of the recessed portion 10R. The number of first regions F and the number of second regions S located around one recessed portion 10R are the same.

The optical member intermediate 10A including the plurality of recessed portions 10R as described above can be prepared by preparing a sheet-like member provided with no recessed portion on the upper surface and removing or deforming a part of the upper surface to form the recessed portions 10R. Alternatively, a liquid resin material is disposed on a support member and cured to form a sheet-like member, and then a part of the upper surface of the sheet-like member is removed or deformed to form the recessed portions; thus, the optical member intermediate 10A can be prepared. Further, the optical member intermediate can be prepared by molding by injection molding, compression molding, or the like using a mold. Alternatively, an optical member intermediate provided with recessed portions may be purchased and prepared. Examples of a method for forming the recessed portions in the sheet-like member include wet etching or dry etching using a mask, laser processing, stamping, and embossing.

(1-2) Step of Irradiating the Optical Member Intermediate with Plasma

Subsequently, the upper surface 10U of the optical member intermediate 10A is irradiated with plasma. By adjusting the condition for plasma irradiation, the processing state of the recessed portion 10R and the peripheral portion 10S can be adjusted.

Then, the upper surface of the intermediate is irradiated with plasma under an atmosphere containing at least one selected from the group consisting of an oxygen radical, CF₄, CHF₃, and SF₆ as a reactive substance. In this manner, the height of the portion located at the center of the first region in a top view can be higher than the height of the second region.

As the condition for plasma irradiation, for example, the concentration of the reactive substance can be in a range from 40 vol % to 100 vol % at an atmospheric pressure in a range from 100 Pa to 300 Pa. In addition, as the plasma, high-frequency plasma (RF-plasma) excited at high frequency is preferred, and the intensity of the power supply at that time can be set in a range from 500 W to 1000 W. The time of plasma irradiation can be, for example, in a range from 60 seconds to 1800 seconds. The temperature during the plasma irradiation can be in a range from 25° ° C. to 100° C. Further, one intermediate may be irradiated with plasma under one irradiation condition, or may be irradiated with plasma under two or more different irradiation conditions. The entire upper surface of the intermediate may be irradiated with plasma, or a part of the upper surface of the intermediate may be irradiated with plasma.

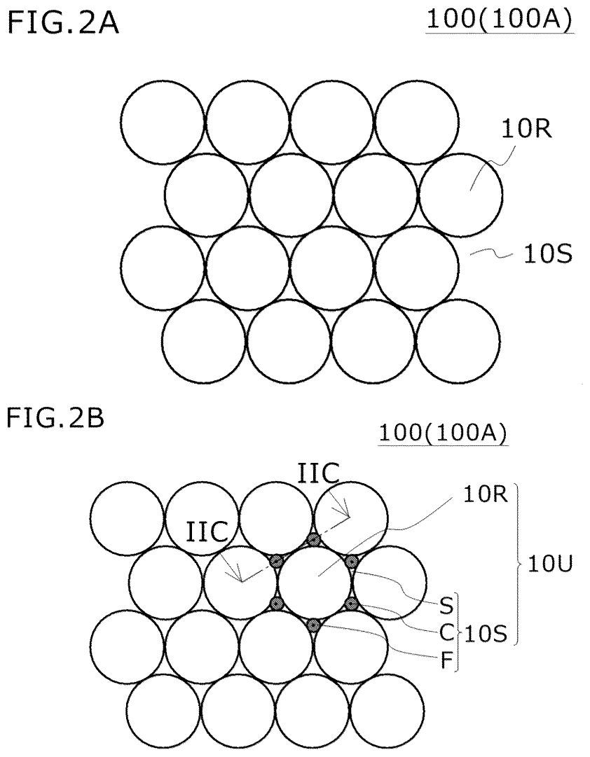

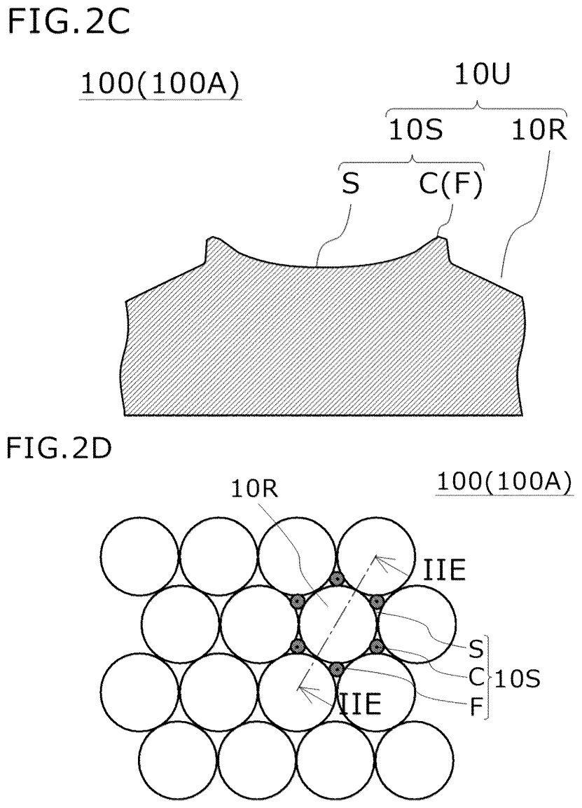

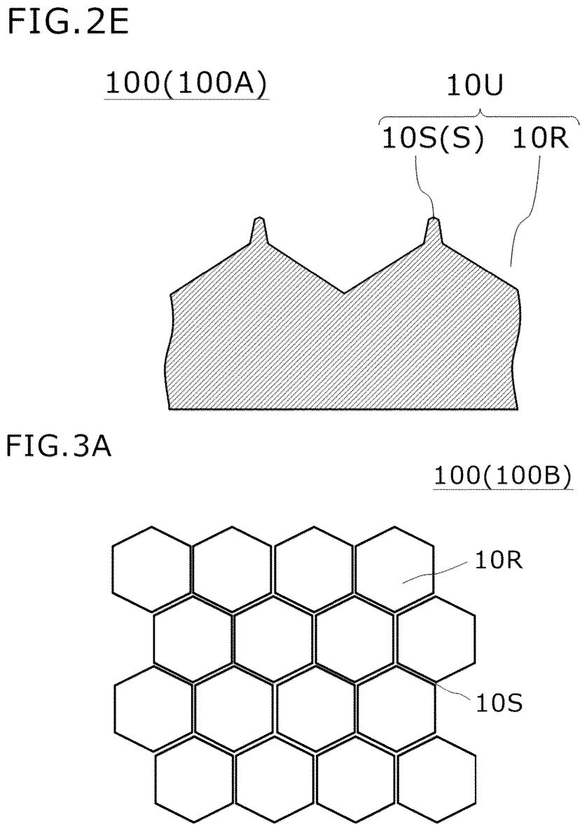

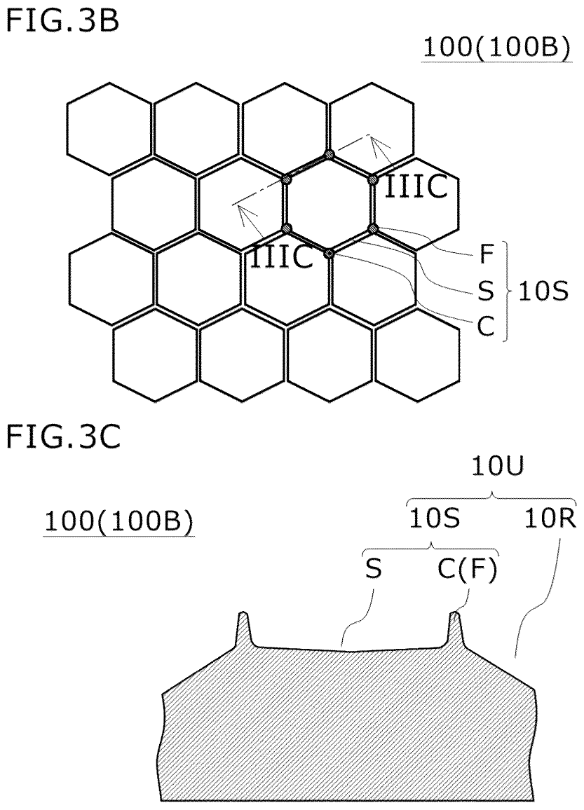

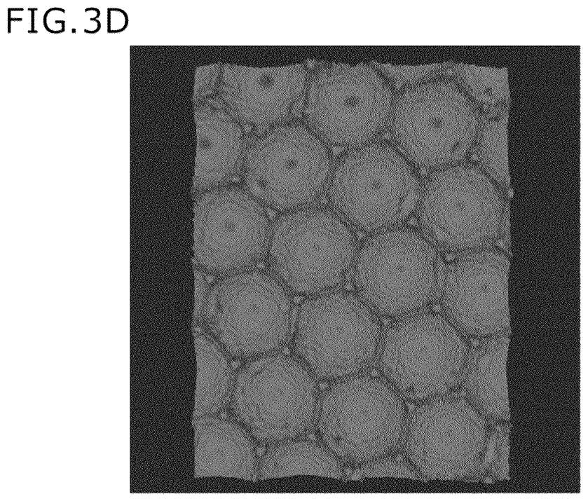

Both of an optical member 100A illustrated in FIGS. 2A to 2E and an optical member 100B illustrated in FIGS. 3A to 3C are obtained using the optical member intermediates 10A having the same shape. These can be obtained by plasma irradiation under different conditions. In the optical member 100B, the depth of the recessed portion 10R is deeper than that in the optical member 100A. In the optical member 100B, the width of the first region F of the peripheral portion 10S is narrower than that in the optical member 100A.

To obtain the optical member having a desired shape, plasma irradiation may be continuously performed or may be performed several times. For example, the optical member intermediate 10A illustrated in FIGS. 1A to 1F is irradiated with plasma under a condition A to obtain the optical member 100A having the shape illustrated in FIG. 2A. After that, the plasma irradiation is stopped once, and thereafter, plasma irradiation is performed again under the same condition A to obtain the optical member 100B illustrated in FIG. 3A. Alternatively, the optical member intermediate 10A illustrated in FIGS. 1A to 1F may be irradiated with plasma under a condition B different from the condition A to obtain the optical member 100B illustrated in FIG. 3A.

The optical member 100A and the optical member 100B obtained by the plasma irradiation as described above include the recessed portions 10R and the peripheral portions 10S in the respective upper surfaces 10U. The peripheral portions 10S of the optical member 100A and the optical member 100B are common in that the height of the second region S is lower than the height of the first region F. The first regions F are illustrated as hatched circular regions in FIGS. 2B, 2D, and 3B.

The optical member 100A will be described first. As illustrated in FIG. 2A, the top view shape of the recessed portion 10R of the optical member 100A is a substantially circular shape, and the recessed portion 10R has a larger diameter than the recessed portion 10R of the optical member intermediate 10A. In other words, in a top view, a proportion of the peripheral portion 10S in the optical member 100A is smaller than a proportion of the peripheral portion 10S in the optical member intermediate 10A. The second region S located on the straight line connecting the centers of the adjacent recessed portions 10R has a flat surface in the optical member intermediate 10A as illustrated in FIG. 1F, and is reduced in width by plasma irradiation as illustrated in FIG. 2E.

As illustrated in FIG. 2C, in the peripheral portion 10S of the optical member 100A, the height of the center C of the first region F is higher than the second region S. The peripheral portion 10S is gradually deeper from the centers C of two first regions F, and is recessed so as to be the deepest at substantially the centers of two second regions S. The depth of the recessed portion including the second region S is shallower than the depth of the recessed portion 10R.

In the optical member 100B, as illustrated in FIGS. 3A and 3D, the top view shape of the recessed portion 10R is close to a hexagonal shape. This is because the centers of the respective recessed portions 10R of the optical member intermediate 10A are disposed so as to be located at the lattice points of a triangular lattice. The recessed portion 10R of the optical member 100B has a larger area than the recessed portion 10R of the optical member 100A illustrated in FIG. 2A.

As illustrated in FIGS. 3C and 3E, also in the peripheral portion 10S of the optical member 100B, the height of the center C of the first region F is higher than that of the second region S as in the optical member 100A. Only exceedingly small regions including the centers C of the first regions F protrude and have a high height. FIGS. 2C and 3C are cross-sectional views of a portion including the second region S sandwiched between the two adjacent recessed portions 10R. In FIG. 2C, a region sandwiched between the two centers C has a shape in which the depth gradually increases such that the vicinity of the center is deepest. On the other hand, in FIG. 3C, exceedingly small regions including the two centers C protrude, and a portion including the second region S sandwiched between the two centers C has an almost even height. This is because the second region S illustrated in FIG. 2C is further irradiated with plasma, and this further narrows the width of the second region S and the reaction from the lateral direction easily proceeds. Thus, only exceedingly small regions including the centers C of the first regions F that are less likely to be affected by the reaction from the lateral direction have such a protruding shape.

An optical member 100 includes a region having a height difference, that is, a non-flat region in the peripheral portion 10S around the recessed portions 10R, and such a region is formed by plasma irradiation. Accordingly, the light emitted from the upper surface of the optical member 100 is emitted as further diffused light compared with the case of an optical member having a flat surface. Therefore, the light-emitting device including the optical member 100 as an emission surface can reduce unevenness in color or unevenness in luminance of the emitted light.

### Variations

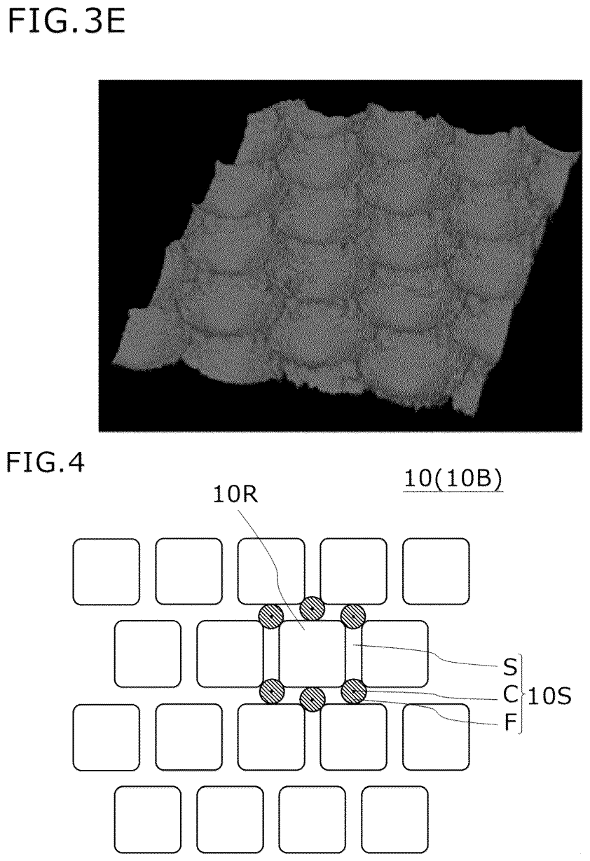

FIGS. 4 to 6 illustrate variations of the optical member intermediate. In an optical member intermediate 10B illustrated in FIG. 4, the opening portion shape of the recessed portion 10R in a top view is a quadrangular shape. Each recessed portion 10R is disposed such that the center of the recessed portion 10R is positioned at a respective one of the lattice points of a triangular lattice. One recessed portion 10R is surrounded by six recessed portions 10R via the surrounding peripheral portion 10S.

The first regions F of the peripheral portion 10S are illustrated as hatched circular regions. Each of the first regions F is a region defined by a circle surrounded by three recessed portions 10R and passing through a point on an outer edge of each of the three recessed portions 10R in a top view. The peripheral portion 10S around one recessed portion 10R includes six first regions F and six second regions S. All of the six first regions F have the same area. Not all of the centers C of the six first regions F are disposed at regular intervals. Specifically, as illustrated in FIG. 4, the six first regions F include two first regions F disposed on one side of the quadrangle and three first regions F disposed on another side of the quadrangle. The three first regions F disposed on one side are disposed at regular intervals. The interval between the centers C of the three first regions F disposed on one side is smaller than the interval between the centers C of the two first regions F disposed on another side. In other words, the six second regions S each sandwiched between the first regions F include four second regions S having small areas and two second regions S having larger areas than the four second regions S.

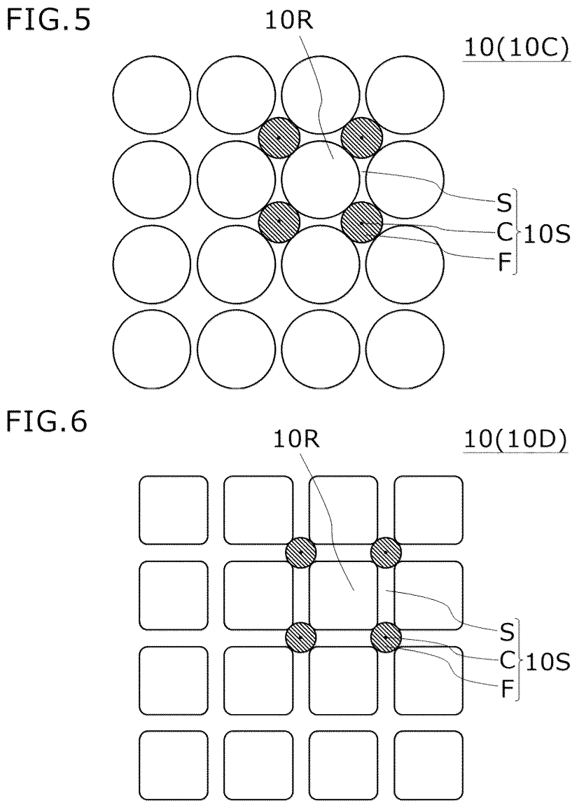

In an optical member intermediate 10C illustrated in FIG. 5, the opening portion shape of the recessed portion 10R in a top view is a circular shape. Each recessed portion 10R is disposed such that the center of the recessed portion 10R is positioned at a respective one of the lattice points of a quadrangular lattice. One recessed portion 10R is surrounded by eight recessed portions 10R via the surrounding peripheral portion 10S.

The first regions F of the peripheral portion 10S are illustrated as hatched circular regions. Each of the first regions F is a region defined by a circle surrounded by four recessed portions 10R and passing through a point on an outer edge of each of the four recessed portions 10R in a top view. The peripheral portion 10S around one recessed portion 10R includes four first regions F and four second regions S. The areas of the four first regions F are all the same, and the centers C of the first regions F are disposed at regular intervals. The areas of the four second regions S are all the same.

In an optical member intermediate 10D illustrated in FIG. 6, the opening portion shape of the recessed portion 10R in a top view is a quadrangular shape. Each recessed portion 10R is disposed such that the center of the recessed portion 10R is positioned at a respective one of the lattice points of a quadrangular lattice. One recessed portion 10R is surrounded by eight recessed portions 10R via the surrounding peripheral portion 10S.

The first regions F of the peripheral portion 10S are illustrated as hatched circular regions. Each of the first regions F is a region defined by a circle surrounded by four recessed portions 10R and passing through a point on an outer edge of each of the four recessed portions 10R in a top view. The peripheral portion 10S around one recessed portion 10R includes four first regions F and four second regions S. The areas of the four first regions F are all the same, and the centers C of the first regions F are disposed at regular intervals. The areas of the four second regions S are all the same.

When the optical member intermediate having the above-described shape is used and subjected to plasma irradiation, the optical member in which the height of the center of the first region is higher than the height of the second region can also be obtained.

### Second Embodiment

The manufacturing method of the light-emitting device according to the second embodiment mainly includes the following steps.
(2-1) Step of preparing the optical member obtained in the first embodiment
(2-2) Step of bonding the optical member and a light-emitting element together

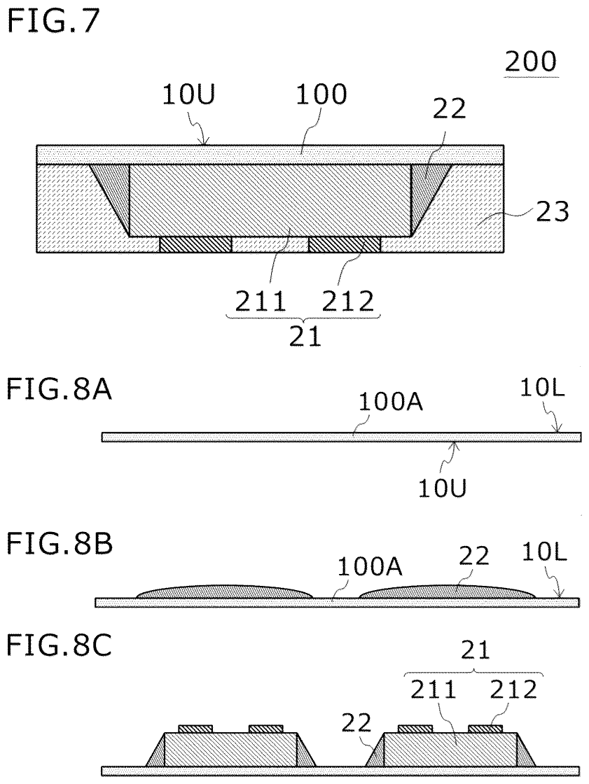

FIG. 7 is an example of the light-emitting device obtained using the manufacturing method of the light-emitting device according to the present embodiment. A light-emitting device 200 includes a light-emitting element 21 and the optical member 100. The optical member 100 is obtained using the manufacturing method of the optical member according to the first embodiment. Furthermore, the light-emitting device 200 can include bonding members 22 and a covering member 23.

(2-1) Step of Preparing the Optical Member Obtained in the First Embodiment

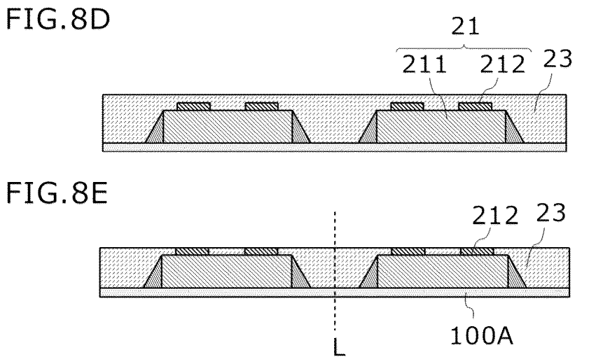

As illustrated in FIG. 8A, the optical member 100 is prepared. Here, the optical member 100A obtained in the first embodiment will be described as an example. The optical member 100A includes the upper surface 10U provided with recessed portions and the lower surface 10L opposite to the upper surface 10U.

First, as illustrated FIG. 8A, the upper surface 10U is disposed facing downward and the lower surface 10L is disposed facing upward. Subsequently, as illustrated in FIG. 8B, the uncured bonding members 22 are disposed on the lower surface 10L of the optical member 100A. An example of a method of disposing the uncured bonding members 22 is potting.

(2-2) Step of Bonding the Optical Member and the Light-Emitting Element Together

The light-emitting element 21 is prepared. The light-emitting element 21 includes a semiconductor layered body 211 and positive and negative electrodes 212, which are a pair of electrodes. As illustrated in FIG. 8C, the light-emitting element 21 is mounted on the bonding member 22 with the electrodes 212 on the upper side. At this time, the bonding member 22 creeps up so as to cover the lateral surfaces of the semiconductor layered body 211.

Subsequently, as illustrated in FIG. 8D, the light-emitting elements 21 and the bonding members 22 are covered with the covering member 23. Here, the covering member 23 is disposed such that the electrodes 212 are entirely embedded. Therefore, as illustrated in FIG. 8E, a step of removing a part of the covering member 23 to expose the electrodes 212 is required. When the covering member 23 is disposed such that the electrodes 212 are exposed in advance, the step of removing a part of the covering member 23 can be omitted. In addition, a step of forming a metal film covering the electrodes 212 exposed from the covering member 23 may be included. Thereafter, by cutting the covering member 23 and the optical member 100A along a cutting line L, the light-emitting device 200 illustrated in FIG. 7 can be obtained.

For the light-emitting device 200, a method of disposing the optical member 100A on the light-emitting element 21 can be used in addition to the method of mounting the light-emitting element 21 on the optical member 100A described above.

### Third Embodiment

The manufacturing method of a light-emitting device according to the third embodiment mainly includes the following steps.
(3-1) Step of preparing a light-emitting device intermediate including the optical member intermediate and a light-emitting element
(3-2) Step of irradiating the light-emitting device intermediate with plasma

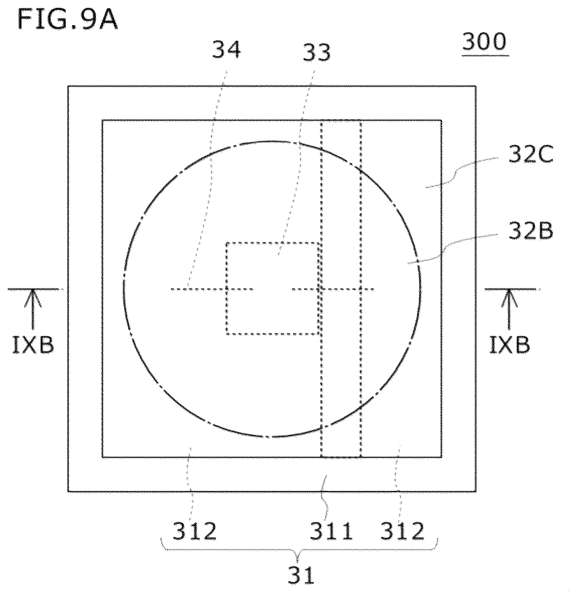

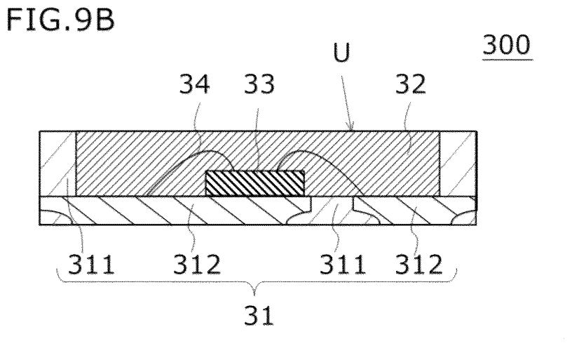

FIGS. 9A and 9B are an example of the light-emitting device obtained using the manufacturing method of the light-emitting device according to the present embodiment. A light-emitting device 300 includes a light-emitting element 33 and an optical member 32. The optical member 32 is obtained using the manufacturing method of the optical member according to the first embodiment. Furthermore, the light-emitting device 300 includes a package 31, the light-emitting element 33 disposed on the package 31, and the optical member 32 that seals the light-emitting element 33. The package 31 includes an insulating base 311 and a conductive member 312. Here, the package 31 including a recessed portion is exemplified, but a flat plate-shaped package without a recessed portion may be used as the package 31. The light-emitting element 33 and the conductive member 312 are electrically connected via a wire 34.

As illustrated in FIGS. 1A to 6 and the like, the upper surface of the optical member 32 sealing the light-emitting elements 33 is provided with a recessed portion and a peripheral portion.

(3-1) Step of Preparing a Light-Emitting Device Intermediate Including the Optical Member Intermediate and the Light-Emitting Element

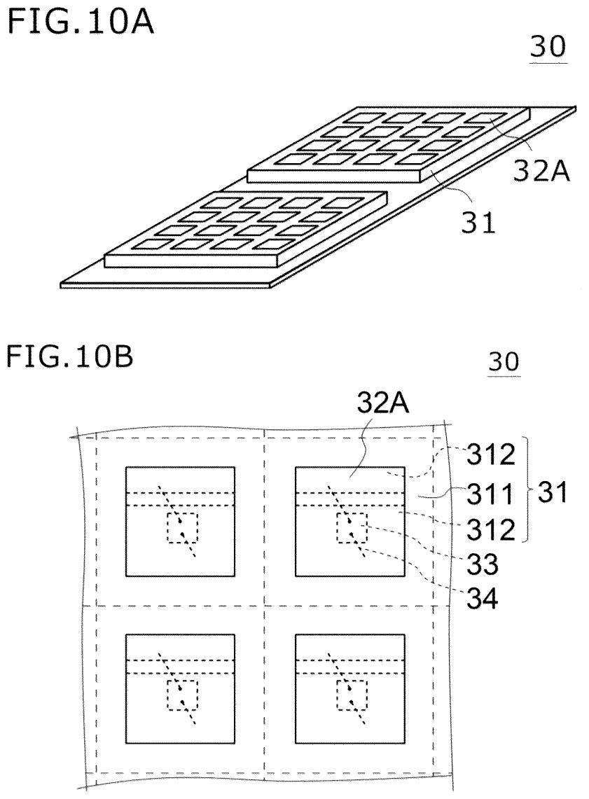

FIGS. 10A and 10B illustrate an example of a light-emitting device intermediate 30. Here, the light-emitting device intermediate 30 includes a plurality of the light-emitting devices 300 as illustrated in FIG. 9A, and the light-emitting devices 300 separated by cutting in a later step can be obtained. Note that a light-emitting device intermediate obtained by singulation performed in advance may be used.

The light-emitting device intermediate to be one light-emitting device has basically the same structure as that of the light-emitting device 300 illustrated in FIG. 7, and differs from the light-emitting device 300 in that the light-emitting device intermediate includes an optical member intermediate 32A to be the optical member 32. That is, an upper surface U of the optical member intermediate 32A of the light-emitting device intermediate 30 is provided with, for example, as illustrated in FIG. 1C and the like, a peripheral portion and a plurality of recessed portions each surrounded by the peripheral portion and recessed from the peripheral portion. The peripheral portion includes a plurality of first regions and a plurality of second regions each sandwiched between the first regions. Each of the first regions is defined by a circle surrounded by three or more of the recessed portions and passing through a point on an outer edge of each of the three or more of the recess portions in a top view.

(3-2) Step of Irradiating the Light-Emitting Device Intermediate with Plasma

The light-emitting device intermediate 30 is irradiated with plasma. At this time, a region other than the optical member intermediates 32A can also be irradiated with plasma. For example, the package 31 can also be irradiated with plasma. Alternatively, the region other than the optical member intermediates 32A may be covered with a mask, and only the optical member intermediates 32A may be irradiated with plasma. The conditions for plasma irradiation are similar to those in the first embodiment. The light-emitting device 300 as illustrated in FIGS. 9A and 9B can be obtained by singulation after the plasma irradiation.

### Variations

The optical member 32 can include two regions including the recessed portions having different sizes. For example, in the example illustrated in FIG. 9A, the optical member 32 (optical member intermediate 32A) having a quadrangular shape in a top view can include a first part 32B including a portion located directly above the light-emitting element 33 and a second part 32C around the first part 32B.

It is assumed that the light-emitting device 300 includes, for example, the light-emitting element 33 having an emission peak wavelength in a range from 440 nm to 470 nm and the optical member 32 including a YAG-based phosphor that absorbs a part of light from the light-emitting element 33 and converts the light into yellow light, and can emit white-based light. In the light-emitting device 300, each of the recessed portions in the first part 32B of the optical member 32 can be larger than each of the recessed portions in the second part 32C. For example, the opening diameter of each of the recessed portions in the first part 32B can be set to 0.2 μm to 1 μm, and the opening diameter of each of the recessed portions in the second part 32C can be in a range from 3 μm to 10 μm.

This can facilitate extraction of, especially, blue light of the light emitted from the first part 32B including the portion located directly above the light-emitting elements 33. Additionally, of the light emitted from the second part 32C, yellow light can be less likely to be emitted.

The members included in the optical member and the light-emitting device will be described in detail below.

### Optical Member

The optical member is transmissive, transmits visible light or ultraviolet light, and transmits 60% or more or preferably 90% or more of light having wavelengths of them. As the material of the optical member, for example, a transmissive thermosetting resin material, such as an epoxy resin or a silicone resin, can be used.

The optical member can contain a wavelength conversion member, such as a phosphor, in the resin material described above. The phosphor can convert light incident on the optical member into light having a different wavelength.

As the phosphor, a yttrium-aluminum-garnet phosphor, a lutetium-aluminum-garnet phosphor, a terbium-aluminum-garnet phosphor, a CCA phosphor, a SAE phosphor, a chlorosilicate phosphor, a silicate phosphor, an oxynitride phosphor, such as a β-SiAION phosphor, a nitride phosphor, such as an LSN phosphor, a BSESN phosphor, an SLA phosphor, a CASN phosphor, or a SCASN phosphor, a fluoride phosphor, such as a KSF phosphor, a KSAF phosphor, or an MGF phosphor, a quantum-dot having a perovskite structure, a II-VI group quantum-dot, a III-V group quantum-dot, or a quantum-dot having a chalcopyrite structure can be used, for example.

The phosphor is preferably disposed at a position separated from the upper surface inside the optical member. Thus, when a part of the upper surface of the optical member is removed by plasma irradiation, removal of the phosphor together with the resin material can be reduced. However, the phosphor may be disposed on the upper surface side of the optical member.

The optical member can contain a light diffusing substance. Examples of the light diffusing substance include fine particles of SiO₂, TiO₂, Al₂O₃, ZnO, or the like.

### Light-Emitting Element

A known semiconductor light-emitting element can be employed as the light-emitting element. In the present embodiment, a light-emitting diode is exemplified as the light-emitting element. For example, as the light-emitting element, a light-emitting element using a nitride semiconductor (InₓAl_{y}Ga_{1-x-y}N, 0≤X, 0≤Y, X+Y≤1) as an element that emits blue light or green light can be used. The shape of the light-emitting element in a plan view can be a quadrangular shape, such as a square shape or a rectangular shape, or a polygonal shape, such as a triangular shape or a hexagonal shape.

### Other Members

As the package, a known package, such as a resin package, a ceramic package, a glass epoxy package, or a COB package, can be used. As the wire, a wire containing Au, Ag, Al, or the like as a main component can be used.

### EXAMPLES

First, an optical member intermediate is prepared. The optical member intermediate is obtained by processing a flat plate-shaped light-transmissive member made of epoxy resin and having a dimension of 10 cm×10 cm and a thickness of 2 mm. The optical member intermediate is provided with a plurality of recessed portions, and the recessed portions are arranged such that the centers of the respective recessed portions are disposed at triangular lattice points. All of the recessed portions have the same size and depth, and each of them has a circular opening portion and is recessed in a hemispherical shape.

### Example 1

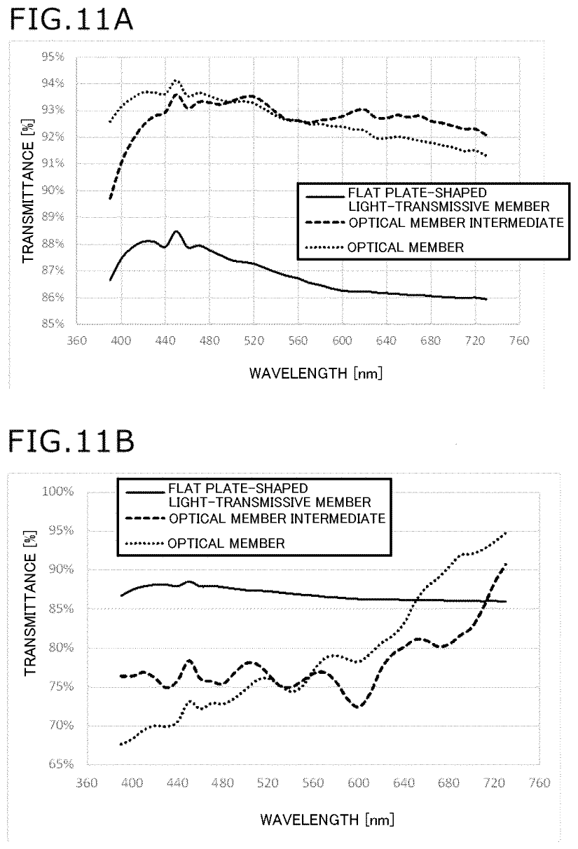

In Example 1, the recessed portions of the optical member intermediate have an opening diameter of 0.75 μm, a depth of 0.2 μm, and a pitch of 1 μm. Such an optical member intermediate was irradiated with plasma in an atmosphere containing an oxygen radical. The treatment conditions were as follows: RF (a high-frequency output of a plasma source) of 600 W, an oxygen flow rate of 200 sccm (a gas flow rate per minute in a standard state), a pressure of 150 Pa, and a temperature of 70° C., and irradiation was performed for 10 minutes. FIG. 11A shows the transmittance of the optical member thus obtained. The transmittance of the optical member is higher than that of the flat plate-shaped light-transmissive member at all wavelengths. At a wavelength shorter than about 500 nm, the transmittance of the optical member is higher than the transmittance of the optical member intermediate. Further, at a wavelength longer than about 560 nm, the transmittance of the optical member is lower than the transmittance of the optical member intermediate. That is, the transmittance can be improved by simply forming the recessed portions compared with that of the flat plate-shaped light-transmissive member without recessed portions, and the transmittance for the light having a short wavelength can be further improved by plasma irradiation.

### Example 2

In Example 2, the recessed portions of the optical member intermediate have an opening diameter of 3.5 μm, a depth of 1.5 μm, and a pitch of 5 μm. Such an optical member intermediate was irradiated with plasma in an atmosphere containing an oxygen radical. The treatment conditions were as follows: RF of 600 W, an oxygen flow rate of 200 sccm, a pressure of 150 Pa, and a temperature of 70° C., and irradiation was performed for 10 minutes. FIG. 11B shows the transmittance of the optical member thus obtained. The transmittance of the optical member is lower than the transmittance of the flat plate-shaped light-transmissive member at a wavelength of about 650 nm or less. At a wavelength shorter than about 500 nm, the transmittance of the optical member is lower than the transmittance of the optical member intermediate. Further, at a wavelength longer than about 550 nm, the transmittance of the optical member is higher than the transmittance of the optical member intermediate. That is, in a long-wavelength region of 720 nm or more, the transmittance can be improved by simply forming the recessed portions compared with that of the flat plate-shaped light-transmissive member without recessed portions, and the transmittance for the light having a long wavelength of 640 nm or more shorter than that can be further improved by plasma irradiation.

What is claimed is:

1. A manufacturing method of an optical member, the manufacturing method comprising:
preparing an optical member intermediate having light transmissivity, the optical member intermediate including an upper surface including a peripheral portion and a plurality of recessed portions each surrounded by the peripheral portion and recessed from the peripheral portion, the peripheral portion including a plurality of first regions and a plurality of second regions each sandwiched between adjacent ones of the first regions, each of the first regions being defined by a circle surrounded by three or more of the recessed portions and passing through a point on an outer edge of each of the three or more of the recess portions in a top view; and
irradiating the upper surface of the optical member intermediate with plasma under an atmosphere containing at least one selected from the group consisting of an oxygen radical, CF₄, CHF₃, and SF₆ to make a height of a center of each of the first regions to be higher than a height of each of the second regions as measured from a lower surface of the optical member intermediate.

2. The manufacturing method of an optical member according to claim 1, wherein
the preparing of the optical member intermediate includes preparing the optical member intermediate so that each of the recessed portions has a circular shape in the top view.

3. The manufacturing method of an optical member according to claim 1, wherein
the preparing of the optical member intermediate includes preparing the optical member intermediate so that each of the recessed portions has a quadrangular shape in the top view.

4. The manufacturing method of an optical member according to claim 1, wherein
the preparing of the optical member intermediate includes preparing the optical member intermediate so that the center of each of the recessed portions is disposed at a respective one of lattice points of a triangular lattice in the top view.

5. The manufacturing method of an optical member according to claim 1, wherein
the preparing of the optical member intermediate includes preparing the optical member intermediate so that the center of each of the recessed portions is disposed at a respective one of lattice points of a quadrangular lattice in the top view.

6. The manufacturing method of an optical member according to claim 1, wherein
the preparing of the optical member intermediate includes preparing the optical member intermediate so that an opening diameter of each of the recessed portions is in a range from 0.2 μm to 50 μm in the top view.

7. The manufacturing method of an optical member according to claim 6, wherein
the preparing of the optical member intermediate includes preparing the optical member intermediate so that a distance between adjacent ones of the recessed portions is in a range from 101% to 150% of the opening diameter of each of the recessed portions.

8. The manufacturing method of an optical member according to claim 1, wherein
an opening diameter of each of the recessed portion is increased by the irradiating of the upper surface of the optical member intermediate with the plasma.

9. The manufacturing method of an optical member according to claim 2, wherein
each of the recessed portion has a circular shape in the top view after the irradiating of the upper surface of the optical member intermediate with the plasma.

10. The manufacturing method of an optical member according to claim 2, wherein
each of the recessed portion has a polygonal shape in the top view after the irradiating of the upper surface of the optical member intermediate with the plasma.

11. A manufacturing method of a light-emitting device, the manufacturing method comprising:
manufacturing an optical member by the manufacturing method of an optical member according to claim 1; and
bonding the optical member and a light emitting element together.

12. A manufacturing method of a light-emitting device, the manufacturing method comprising:
preparing a light-emitting device intermediate including
a light-emitting element, and
an optical member intermediate including an upper surface and a plurality of recessed portions formed in the upper surface and spaced apart from each other, the upper surface including a plurality of first regions and a plurality of second regions each sandwiched between adjacent ones of the first regions, each of the first regions being defined by a circle surrounded by three or more of the recessed portions and passing through a point on an outer edge of each of the three or more of the recess portions in a top view; and
irradiating the upper surface of the optical member intermediate with plasma under an atmosphere containing at least one selected from the group consisting of an oxygen radical, CF₄, CHF₃, and SF₆ to make a height of a center of each of the first regions to be higher than a height of each of the second regions as measured from a lower surface of the optical member intermediate.
